(19) United States
(12) Patent Application Publication
(10) Pub. No.: US 2008/0044990 A1
(43) Pub. Date: Feb. 21, 2008

(54) Method for Fabricating A Semiconductor Device Comprising Surface Cleaning

(75) Inventor: Sang Ho Lee, Ulsan-Si (KR)

Correspondence Address: MARSHALL, GERSTEIN & BORUN LLP, 233 S. WACKER DRIVE, SUITE 6300, SEARS TOWER, CHICAGO, IL, 60606, US

(73) Assignee: HYNIX SEMICONDUCTOR INC., Gyeonggi-do (KR)

(21) Appl. No.: 11/771,498

(22) Filed: Jun. 29, 2007

(30) Foreign Application Priority Data
Aug. 18, 2006 (KR) 10-2006-0078351

(51) Int. Cl. H01L 21/3205; C23G 1/02; H01L 21/4763

(52) U.S. Cl. 438/586; 134/2; 134/3; 438/675; 257/E21.294; 257/E21.495

(57) ABSTRACT

A method for fabricating a semiconductor device including surface cleaning includes forming a gate stack on a semiconductor substrate, cleaning contaminants present on the surface of the semiconductor substrate exposed through a contact hole using an etchant including a fluorine (F)-containing species dispersed in an alcohol, and filling a contact hole with a conductive layer to form a connection contact. The etchant preferably has a low selectivity of 1 or less.

### CROSS-REFERENCE TO RELATED APPLICATION

The priority of Korean patent application number 10-2006-0078351, filed on Aug. 18, 2006, the disclosure of which is incorporated by reference in its entirety, is claimed.

### BACKGROUND

The invention relates to a method for fabricating a semiconductor device. More specifically, the invention relates to a method for fabricating a semiconductor device including a surface cleaning step to remove contaminants (e.g., native oxides) from the surface of semiconductor device layers.

With reductions in the design rule for semiconductor devices, supershort channel-type metal oxide semiconductor (MOS) transistors having a fine line critical dimension (CD) of 80 nm or less have been integrated on semiconductor substrates. In addition, the reduction in the design rule has introduced limitations in the process margin as well as restrictions on the removal of surface contaminants (e.g., native oxides) during the formation of connection wiring structures or devices.

For example, connection contacts come in contact with junctions such as sources and/or drains of transistors, and are thus connected thereto. To secure the contact area of the connection contacts, the connection contacts are formed with a self aligned contact (SAC) using a gate stack as an etching barrier. To reduce resistance between the junctions and the connection contacts when using the SAC, contaminants (e.g., native oxides) present on the surface of the junction are removed prior to depositing a conductive plug layer.

The process of removing native oxides is generally carried out by wet cleaning using a buffered oxide etchant (BOE) or a diluted hydrofluoric acid (HF) solution as a wet etchant. During wet cleaning, there occurs undesirable corrosion loss of an insulating layer constituting the sidewalls of contact holes. The corrosion loss is a restriction or limiting factor of wet cleaning.

More specifically, the reduction in the design rule for semiconductor devices causes a small-sized linewidth of an insulating layer for isolating adjacent contact holes from each other. Accordingly, the loss of the insulating layer during conventional wet cleaning makes it difficult to secure a predetermined space between adjacent contact holes. As a result, an electric short circuit between connection contacts filling the contact holes may occur. In addition, a leakage current in transistors connected to the connection contacts may occur.

Therefore, there is a need to develop a surface cleaning method capable of efficiently removing native oxides while preventing the corrosion of neighboring layers, e.g., insulating layers, conductive layers, or semiconductor layers.

### BRIEF SUMMARY OF THE INVENTION

An aspect of the invention provides a method for fabricating a semiconductor device including surface cleaning capable of efficiently removing a native oxide while preventing the corrosion loss of interlayer dielectric layers.

In accordance with one aspect, the invention provides a method for fabricating a semiconductor device, the method including cleaning contaminants present on the surface of a cleaning target layer using an etchant including a fluorine (F)-containing species dispersed in an alcohol.

In accordance with another aspect, the invention provides a method for fabricating a semiconductor device including: forming an insulating layer on an underlying layer; selectively etching the insulating layer to form a contact hole to expose the surface of the underlying layer and create contaminants on the surface of the underlying layer; cleaning the contaminants present on the surface of the underlying layer exposed through the contact hole using an etchant including a fluorine (F)-containing species dispersed in an alcohol; and filling the contact hole with a conductive layer to form a connection contact.

In accordance with yet another aspect, the invention provides a method for fabricating a semiconductor device including: forming a plurality of gate stacks on a semiconductor substrate, each gate stack including a first conductive layer, a spacer on the side of the gate stack, and a capping layer on the top of the gate stack; forming an insulating layer over the gate stacks to fill the region between adjacent gate stacks; etching the insulating layer using the spacer and the capping layer as etching barriers to form a contact hole and create contaminants on the surface of the semiconductor substrate; cleaning the contaminants present on the surface of the semiconductor substrate exposed through the contact hole using an etchant comprising a fluorine (F)-containing species dispersed in an alcohol; forming a second conductive layer over the resulting structure such that the second conductive layer fills the contact hole; and planarizing the second conductive layer, thereby exposing the capping layer and forming connection contacts separated from each other by the gate stack and the remaining insulating layer.

The cleaning target layer is preferably a silicon substrate, a polycrystalline silicon layer, an amorphous silicon layer, a tungsten (W) layer, a tungsten nitride (WN) layer, a tungsten silicide (WSiₓ) layer, a titanium (Ti) layer, a titanium nitride (TiN) layer, a copper (Cu) layer, an aluminum (Al) layer, or a zinc (Zn) layer.

The alcohol preferably includes isopropyl alcohol (IPA), and the fluorine (F)-containing species preferably includes hydrofluoric acid (HF), fluoride ions (F⁻), and/or bifluoride ions (HF₂⁻), and the etchant is preferably not less than 80% by weight of the alcohol and less than 20% by weight of the fluorine (F)-containing species.

The alcohol can also include glycol, in which case the fluorine (F)-containing species preferably includes hydrofluoric acid (HF), fluoride ions (F⁻), and/or bifluoride ions (HF₂⁻), and the etchant is preferably not less than 80% by weight of the alcohol, and less than 20% by weight of the fluorine (F)-containing species.

The etchant preferably includes a surfactant as a dispersant for the fluorine (F)-containing species.

The water content in the etchant is preferably less than 10% by weight.

The etchant is preferably prepared by mixing the alcohol with a hydrofluoric acid (HF) solution.

The cleaning is preferably carried out using the etchant to remove native oxide or etching residue present on the surface of the cleaning target layer or the semiconductor substrate.

The insulating layer is preferably made of at least one of boron phosphorus silicate glass (BPSG), phosphorus silicate glass (PSG), borosilicate glass (BSG), low pressure tetra ethyl ortho silicate (LP-TEOS), plasma enhanced tetra ethyl ortho silicate (PE-TEOS), high density plasma (HDP) silicon oxide, undoped silicate glass (USG), low pressure (LP) nitride, plasma enhanced (PE) nitride, silicon oxynitride, spin-on-dielectric (SOD), and a thermal oxide.

The first conductive layer preferably includes a gate layer having a underlying gate dielectric layer, the spacer and the capping layer preferably includes a silicon nitride layer, the insulating layer preferably includes a boron phosphorus silicate glass (BPSG) layer. The method preferably further includes forming a spacer insulating layer including an undoped silicate glass (USG) layer such that the spacer insulating layer covers the spacer and the capping layer.

The amount of the fluorine (F)-containing species contained in the etchant is preferably selected to adjust each etching ratio of the insulating layer, the spacer and the capping layer to native oxide to 3 or less.

The invention provides a method for fabricating a semiconductor device including surface cleaning capable of efficiently removing a native oxide while preventing the corrosion loss of interlayer dielectric layers.

### BRIEF DESCRIPTION OF THE DRAWINGS

FIGS. 1 to 3 are cross-sectional views schematically illustrating a method for fabricating a semiconductor device including surface cleaning according to one embodiment of the invention; and

FIGS. 4 to 9 are cross-sectional views illustrating schematically an alternate method for fabricating a semiconductor device including surface cleaning according to another embodiment of the invention.

### DETAILED DESCRIPTION OF THE INVENTION

The invention is directed to a method for cleaning contaminants on the surface of cleaning target layers using an etchant including a fluorine (F)-containing species dispersed in an alcohol. The cleaning target layer may be a non-oxide layer, e.g., a mono crystalline silicon layer or a polycrystalline silicon layer such as a silicon substrate for example. The cleaning target may be native oxide created by spontaneous oxidation on the surface of the cleaning target layer. The cleaning target layer may be a silicon substrate, a polycrystalline silicon layer, an amorphous silicon layer, a tungsten (W) layer, a tungsten nitride (WN) layer, a tungsten silicide (WSiₓ) layer, a titanium (Ti) layer, a titanium nitride (TiN) layer, a copper (Cu) layer, an aluminum (Al) layer, or a zinc (Zn) layer, for example.

Silicon oxide is an example of a native oxide. Native oxides have highly densified covalent bonds, when compared to silicon oxides formed by a deposition method such as chemical vapor deposition (CVD) or spin coating. For this reason, native oxides exhibit a low etching ratio by an etchant (e.g., a diluted HF solution), as compared to the deposited silicon oxides. In the process of removing native oxides from the surface of cleaning target layers exposed through the silicon oxide deposition layers, a serious loss of the silicon oxide deposition layers may unexpectedly occur. When forming self aligned contacts (SACs), undesirable phenomena occur, e.g., a short circuit between connection contacts, or a leakage current in transistors connected to the connection contacts.

In one embodiment, the invention is directed to a method for removing contaminants on the surface of the cleaning target layers, which method is capable of preventing the unintended loss of other deposition layers including a silicon oxide layer by using an etchant comprising a fluorine (F)-containing species dispersed in an alcohol.

The fluorine (F)-containing species can include hydrofluoric acid (HF), fluoride ions (F⁻), and/or bifluoride ions (HF₂⁻). The fluorine (F)-containing species is present in a dispersed state in an alcohol. To facilitate the dispersion, the etchant may further include a surfactant. The dispersion of the fluorine (F)-containing species is created by mixing a hydrofluoric acid (HF) solution with an alcohol. At this time, the amount of water (H₂O) contained in the etchant is desirably adjusted to less than 10%.

The alcohol is generally an organic liquid having at least one hydroxyl group per molecule. Examples of suitable alcohols include isopropyl alcohol (IPA: (CH₃)₂CHOH), and glycols of organic compounds in which two hydroxyl groups are bonded to different carbons. Glycols include organic compounds having carbons (C), hydrogen (H), and hydroxyl groups (OH), for example ethylene glycol (CH₂OHCH₂OH). When the alcohol includes ethylene glycol, the ethylene glycol is used in a stoichiometric amount sufficient to adjust the physical properties of the etchant to be suitable for use in a semiconductor process.

The glycol is considered to be effective in lowering the etching selectivity ratio (e.g., to about 3 or less, preferably, to 1 or less) of a deposited layer relative to a native oxide. This takes into consideration the fact that the deposited insulating layer made, for example, of boron phosphorus silicate glass (BPSG) has a very large etching ratio relative to a native oxide when using a dilute HF solution as an etchant. The etchant according to one embodiment of the invention is a low-selectivity etchant that enables the etching ratio of a deposited layer relative to a native oxide to be adjusted to a low level.

The etchant of the invention is experimentally demonstrated to reduce the difference in etching selectivity between a deposited oxide layer and a native oxide. In particular, the etchant has a low etching rate on a BPSG layer, which is generally used as an interlayer dielectric layer in a semiconductor device. Thus, the etchant is effective in removing contaminants from the surfaces of underlying junctions or conductive layers without causing damage to the interlayer dielectric layer when forming contacts.

Accordingly, the cleaning method of the invention can be used in a cleaning step for removing native oxides during etching processes (e.g., SAC) in which the prevention of interlayer dielectric layer loss is beneficial. Furthermore, the cleaning method of the invention can be also utilized in a variety of applications including other semiconductor fabrication processes involving the removal of native oxides, and processes to remove other surface contaminants, e.g., etching residues.

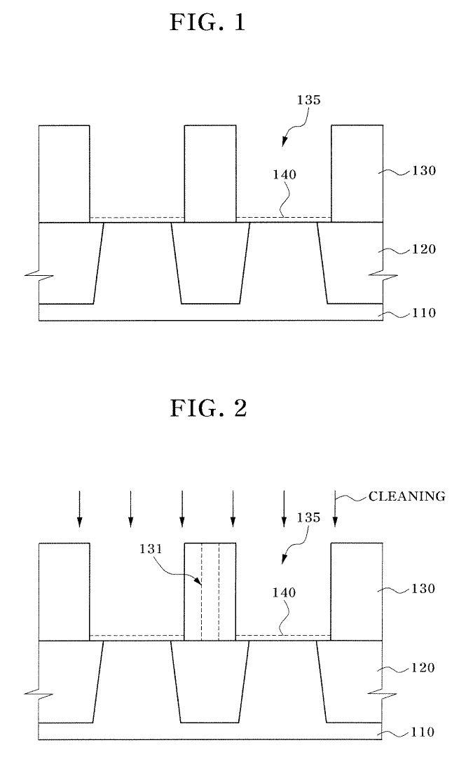

FIGS. 1 to 3 are cross-sectional views schematically illustrating a method for fabricating a semiconductor device including surface cleaning according to one embodiment of the invention. In one embodiment, a process for cleaning the surface of a cleaning target layer exposed through an insulating layer is illustrated.

Referring to FIG. 1, a semiconductor substrate 110 as a cleaning target layer is introduced. At this time, a device isolation layer 120 having a shallow trench isolation (STI) structure is formed on the semiconductor substrate 110. The device isolation layer 120 typically includes a silicon oxide layer. An insulating layer 130 having a contact hole 135 or opening is formed on the semiconductor substrate 110, such that the surface of the semiconductor substrate 110 is partially exposed through the contact hole 135 or opening. The insulating layer 130 preferably includes a silicon oxide layer. A surface contaminant 140, e.g., a native oxide, created by spontaneous oxidation of the silicon may be formed on the surface of the semiconductor substrate 110 exposed through the contact hole 135 of the insulating layer 130. The surface contaminant 140 may further include an etching residue involved in etching of the contact hole 135.

Referring to FIG. 2, the surface contaminant 140 is subjected to wet cleaning using an etchant including a fluorine (F)-containing species dispersed in an alcohol. The alcohol (e.g., including isopropyl alcohol (IPA) and/or glycol) is preferably used in an amount of not less than 80%, based on the total weight of the etchant. The fluorine (F)-containing species e. g., including hydrofluoric acid (HF), fluoride ions (F⁻), and/or bifluoride ions (HF₂⁻)) is used in an amount less of than 20%, based on the total weight of the etchant. In particular, glycol is experimentally demonstrated to contribute to an efficient reduction in the etching rate of the insulating layer. The percentage (%) representing the amount of each constituent component of the etchant is a percentage by weight (wt %).

The insulating layer 130 may include a boron phosphorus silicate glass (BPSG). The BPSG contains about 20 mol % or less boron, and about 30 mol % or less phosphorus. The BPSG has a structure in which covalent bonds between silicon atoms and oxygen atoms are poorly densified due to the presence of boron and phosphorus atoms. More specifically, a native oxide has a structure based on covalent bonds between silicon atoms and oxygen atoms, while the BPSG has a structure in which the covalent bonds are sporadically broken due to the presence boron and phosphorus atoms. Accordingly, the BPSG has a relatively poorly densified silicon oxide structure.

Accordingly, when the surface contaminant 140 is removed in accordance with conventional cleaning methods using a diluted HF solution, the etching rate of the BPSG is large compared to that of the native oxide. As a result, the width of the contact holes 135 increases, and the remaining portion 131 of the insulating layer 130 is considerably reduced. In addition, the contact holes 135 may be lost along with a bridge formed therebetween.

On the other hand, in the case where the etchant of the invention is used for etching, the fluorine species breaks covalent bonds of the silicon oxide, but the alcohol (e.g., glycol) passivates the functional groups broken in the BPSG, thus reducing the difference in electronegativity between the functional groups. Accordingly, the alcohol in the etchant reduces the etching ratio of the BPSG relative to a native oxide. As a result, the etchant of the present invention is effective in lowering the etching selectivity ratio (e.g., to about 3 or less) of the BPSG relative to a native oxide.

In conventional wet cleaning methods using a diluted HF or a 300:1 BOE (buffer oxide etch) solution (e.g., LAL15), the etching ratio of the BPSG relative to a native oxide is known to be not less than 5, more specifically, about 7 to 8, even more specifically, 9 or more. That is, the BPSG is estimated to be removed at an etching rate of about 7 to 8 times faster than the native oxide.

On the other hand, in the case where the etchant containing the glycol and fluorine species according to the invention is used for etching, it is experimentally demonstrated that an etching selectivity ratio less than 1 can be realized. That is to say, the etching rate of deposited oxides, such as BPSG, is substantially equivalent to or lower than that of native oxides. As a result, the unintended corrosion loss of the insulating layer 130 (e.g., BPSG) caused by removing the native oxide can be more efficiently prevented. For this reason, problems involved in the loss of the insulating layer 130 can be solved.

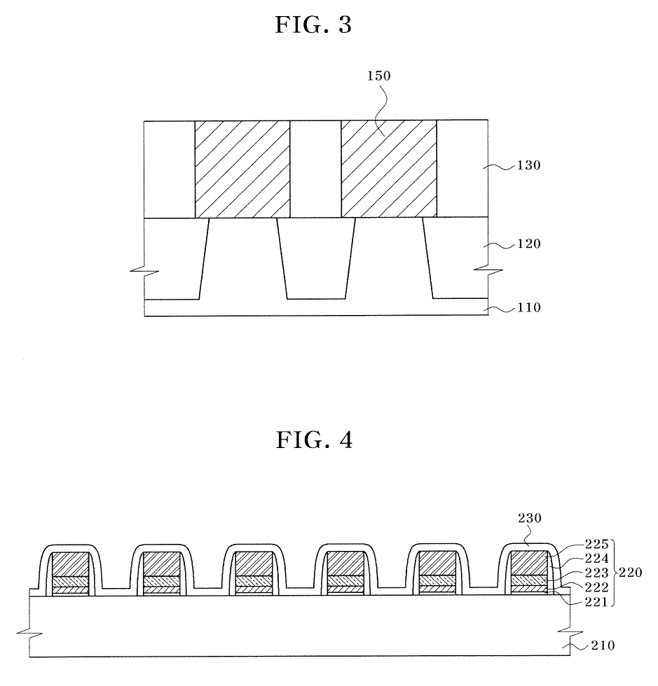

Referring to FIG. 3, a conductive layer is formed such that it fills the contact hole 135 where the surface contaminant 140 including the native oxide is removed. The conductive layer is planarized by chemical mechanical polishing (CMP) or an etch-back process to form connection contacts 150 or plugs. At this time, loss of the insulating layer 130 does not occur, and thus a predetermined space between adjacent connection contacts 150 can be sufficiently maintained.

As is apparent from the foregoing, although the monocrystalline silicon region (or junctions formed in the region) in the semiconductor substrate 110 is mentioned as the cleaning target layer, the cleaning method according to the invention can be applied to clean the surfaces of other layers, e.g., conductive layers, silicon layers, or semiconductor substrate layers. For example, the cleaning target layer may be a silicon substrate, a polycrystalline silicon layer, an amorphous silicon layer, a tungsten (W) layer, a tungsten nitride (WN) layer, a tungsten silicide (WSiₓ) layer, a titanium (Ti) layer, a titanium nitride (TiN) layer, a copper (Cu) layer, an aluminum (Al) layer, or a zinc (Zn) layer. The etchant of the invention has a low etching selectivity ratio (e.g., of about 3 or less) of the cleaning target layer relative to that of a native oxide. The native oxide can be removed from the surface of the cleaning target layer while corrosion loss of the cleaning target layer is inhibited.

As mentioned above, the BPSG is exemplified as the material for the insulating layer. In general, however, the insulating layer, can include boron phosphorus silicate glass (BPSG), phosphorus silicate glass (PSG), borosilicate glass (BSG), low temperature tetra ethyl ortho silicate (LP-TEOS), plasma enhanced tetra ethyl ortho silicate (PE-TEOS), high density plasma (HDP) silicon oxide, undoped silicate glass (USG), low pressure (LP) nitride, plasma enhanced (PE) nitride, silicon oxynitride, spin-on-dielectric (SOD), and thermal oxide. The etchant of the invention has a low etching selectivity ratio (e.g., of about 3 or less, preferably, of 1 or less) of the insulating layer material relative to a native oxide.

The etchant according to one embodiment of the invention can be used for both cleaning to remove the surface contaminant 140 such as a native oxide and cleaning to remove an etching residue in addition to the native oxide. In addition, the etchant can be utilized in a variety of applications including a cleaning process prior to formation of contacts 150 as described above, a SAC process, and semiconductor fabrication processes involving the removal of a native oxide.

FIGS. 4 to 9 are cross-sectional views illustrating schematically an additional method for fabricating a semiconductor device including surface cleaning according to another embodiment of the invention.

Referring to FIG. 4, a surface cleaning solution and a cleaning method according to the invention can be applied to a SAC process. As a result, the electric wiring reliability can be improved by prevening deterioration in the performance of a supershort channel-type MOS transistor which can result from loss of or damage to an interlayer dielectric layer.

First, a semiconductor substrate 210 is subjected to shallow trench isolation (STI). Gate stacks 220 are formed on the semiconductor substrate 210. Each gate stack 220 includes a gate dielectric layer 221, a first conductive layer 222 and 223 as a gate layer, a silicon nitride (SiN) spacer 224 arranged on the side of the gate stack 220, and a capping layer 225 as a silicon nitride mask layer on the top of the gate stack 220.

The spacer 224 may include a silicon nitride (SiN) layer having a thickness of about 5 Å to 300 Å. Alternatively, the spacer 224 may include a double-layered structure including a silicon nitride layer and a silicon oxide layer. The first conductive layer 222, 223 has a multi-layered structure including of a lower conductive layer 222 made of a barrier metallic layer or a polycrystalline silicon layer, and an upper conductive layer 223 made of a tungsten layer or a tungsten silicide layer. A spacer insulating layer 230 made of a undoped silicate glass (USG) layer is formed to a thickness of 1,000 Å or less. The undoped silicate glass (USG) layer is deposited by ambient pressure chemical mechanical deposition (APCMD), low pressure chemical mechanical deposition (LPCMD) or atomic layer deposition (ALD).

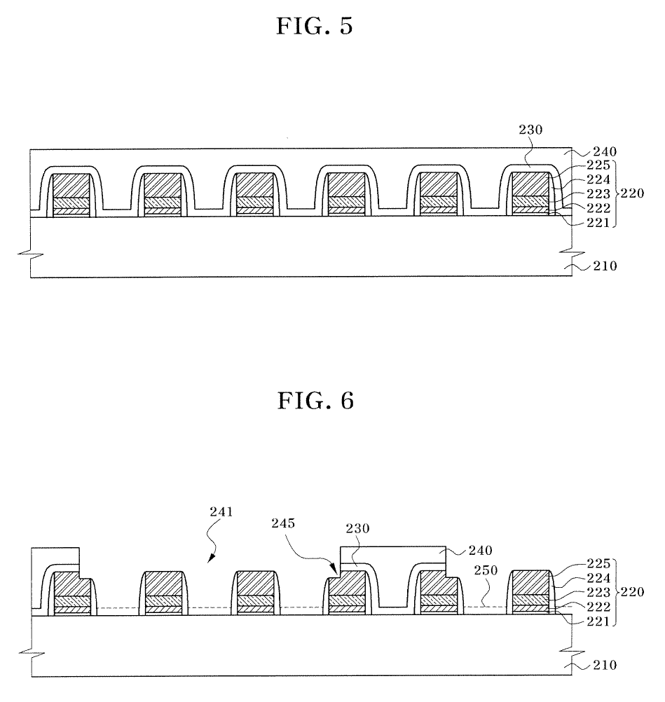

Referring to FIG. 5, an interlayer dielectric layer 240 is formed on the spacer insulating layer 230 such that it covers the gate stack 220. The interlayer dielectric layer 240 preferably includes a BPSG layer. The BPSG layer contains about 20 mol % or less boron, and about 30 mol % or less of phosphorus. Then, the BPSG layer is planarized.

Referring to FIG. 6, the interlayer dielectric layer 240 is etched using the spacer and the capping layer as etching barriers to form a contact hole 241 or opening extended to expose a plurality of gate stacks 220 to the outside. This process is carried out in accordance with a SAC process. The capping layer 225 may be partially etched, and thus a lost part 245 is formed.

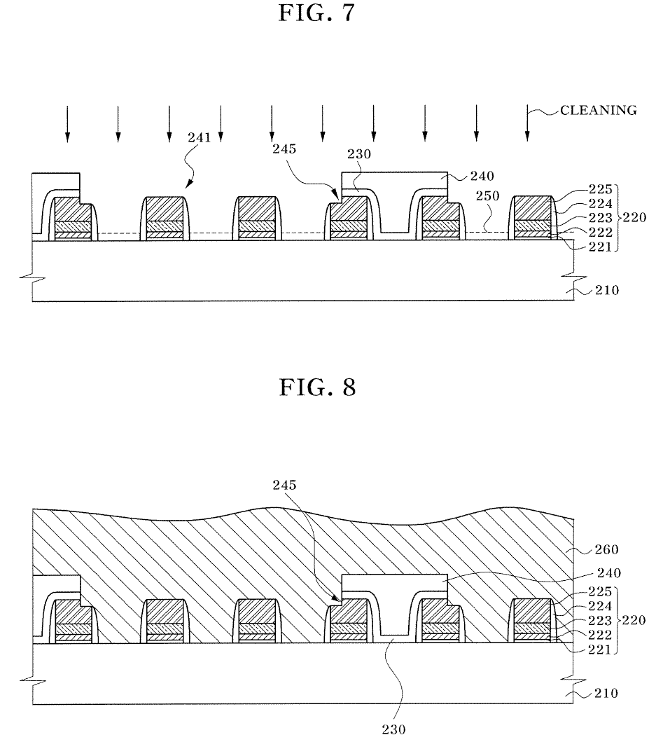

Referring to FIG. 7, contaminants 250 present on the surface of the semiconductor substrate 200 exposed through the contact hole 241 are cleaned using an etchant comprising a flourine (F)-containing species dispersed in an alcohol. Such cleaning enables the contaminants 250 (e.g., native oxides) to be removed from the surface of the semiconductor substrate 210, while preferably preventing the loss of the interlayer dielectric layer, as mentioned with reference to FIG. 2.

Referring to FIG. 8, a second conductive layer 260 is formed over the resulting structure such that it fills the cleaned contact hole 241. The formation of the second conductive layer 260 is preferably carried out by depositing a doped polycrystalline silicon layer.

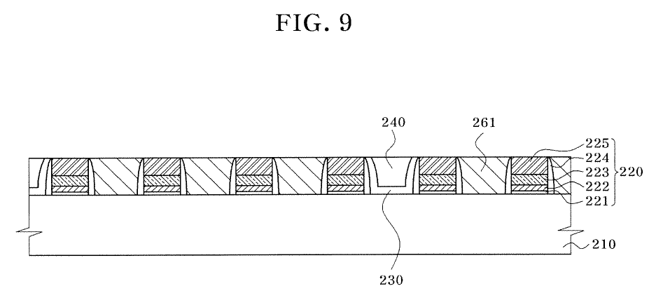

Referring to FIG. 9, the second conductive layer 260 is planarized by CMP such that the capping layer 225 is exposed to the outside. As a result, connection contacts 261 are formed such that they are separated from each other by the gate stacks 220 and the remaining interlayer dielectric layer 240. The connection contacts 261 may be considered to function as plugs connected to junctions of transistors.

As is apparent from the foregoing, according to the invention, a cleaning step having a low etching selectivity ratio of a deposited layer (e.g., interlayer dielectric layer) relative to a native oxide can be realized using an etchant containing a fluorine (F)-containing species and an alcohol. The cleaning of the invention prevents the loss of other layers exposed to the etchant during cleaning. That is, the etchant enables a reduction in the etching selectivity ratio of deposited layers (i.e., insulating layers, conductive layers, or semiconductor substrate) relative to a native oxide, thus removing native oxides while efficiently preventing the corrosion loss of the deposited layers caused by the etchant.

Accordingly, in highly integrated devices having a fine line-width of 80 nm or less, the deterioration in the performance of MOS transistors caused by the unintended loss of deposited layers (e.g., interlayer dielectric layer) when cleaning to remove native oxides can be prevented. In addition, during SAC processes, undesirable phenomena can be prevented, e.g., short circuit or leakage current between connection contacts which results from the loss of the interlayer dielectric layer functioning to secure a predetermined space between adjacent contact holes.

Although preferred embodiments of the invention have been disclosed for illustrative purposes, those skilled in the art will appreciate that various modifications, additions, and substitutions are possible, without departing from the scope and spirit of the invention as defined in the accompanying claims.

What is claimed is:

1. A method for fabricating a semiconductor device, the method comprising cleaning contaminants on the surface of a cleaning target layer using an etchant comprising a fluorine (F)-containing species dispersed in an alcohol.

2. The method according to claim 1, wherein the cleaning target layer is selected from the group consisting of silicon substrates, polycrystalline silicon layers, amorphous silicon layers, tungsten (W) layers, tungsten nitride (WN) layers, tungsten silicide (WSiₓ) layers, titanium (Ti) layers, titanium nitride (TiN) layers, copper (Cu) layers, aluminum (Al) layers, and zinc (Zn) layers.

3. The method according to claim 1, wherein:
the alcohol comprises isopropyl alcohol (IPA),
the fluorine (F)-containing species comprises at least one of hydrofluoric acid (HF), fluoride ions (F⁻), and bifluoride ions (HF₂⁻), and
the etchant comprises not less than 80% by weight of the alcohol and less than 20% by weight of the fluorine (F)-containing species.

4. The method according to claim 1, wherein:
the alcohol comprises a glycol,
the fluorine (F)-containing species comprises at least one of hydrofluoric acid (HF), fluoride ions (F⁻), and bifluoride ions (HF₂⁻), and
the etchant comprises not less than 80% by weight of the alcohol, and less than 20% by weight of the fluorine (F)-containing species.

5. The method according to claim 1, wherein the etchant further comprises a surfactant as a dispersant for the fluorine (F)-containing species.

6. The method according to claim 1, wherein the etchant comprises less than 10% by weight water.

7. The method according to claim 1, comprising preparing the etchant by mixing the alcohol with a hydrofluoric acid (HF) solution.

8. The method according to claim 1, wherein the step of cleaning contaminants comprises using the etchant to remove a native oxide present on the surface of the cleaning target layer.

9. A method for fabricating a semiconductor device, the method comprising cleaning contaminants on the surface of a cleaning target layer exposed through an insulating layer using an etchant comprising a fluorine (F)-containing species dispersed in an alcohol.

10. The method according to claim 9, wherein:
the alcohol comprises at least one of isopropyl alcohol (IPA) and glycol,
the fluorine (F)-containing species comprises at least one of hydrofluoric acid (HF), fluoride ions (F⁻), and bifluoride ions (HF₂⁻), and
the etchant comprises not less than 80% by weight of the alcohol, and less than 20% by weight of the fluorine (F)-containing species.

11. The method according to claim 9, wherein the insulating layer is selected from the group consisting of boron phosphorus silicate glass (BPSG), phosphorus silicate glass (PSG), borosilicate glass (BSG), low pressure tetra ethyl ortho silicate (LP-TEOS), plasma enhanced tetra ethyl ortho silicate (PE-TEOS), high density plasma (HDP) silicon oxide, undoped silicate glass (USG), low pressure (LP) nitride, plasma enhanced (PE) nitride, silicon oxynitride, spin-on-dielectric (SOD), thermal oxide, and combinations thereof.

12. A method for fabricating a semiconductor device comprising:
forming an insulating layer over an underlying layer;
selectively etching the insulating layer to form a contact hole exposing the surface of the underlying layer;
cleaning the contact hole using an etchant comprising a fluorine (F)-containing species dispersed in an alcohol; and
filling the contact hole with a conductive layer.

13. The method according to claim 12, wherein:
the alcohol comprises at least one of isopropyl alcohol (IPA) and glycol,
the fluorine (F)-containing species comprises at least one of hydrofluoric acid (HF), fluoride ions (F⁻), and bifluoride ions (HF₂⁻), and
the etchant comprises not less than 80% by weight of the alcohol and less than 20% by weight of the fluorine (F)-containing species.

14. A method for fabricating a semiconductor device comprising:
forming a plurality of gate stacks over a semiconductor substrate, each gate stack including a first conductive layer, a spacer on the side of the gate stack, and a capping layer on the top of the gate stack;
forming an insulating layer over the gate stacks, thereby filling the region between adjacent gate stacks;
etching the insulating layer to form a contact hole by using the spacer and the capping layer as etching barriers;
cleaning the contact hole using an etchant comprising a fluorine (F)-containing species dispersed in an alcohol;
forming a second conductive layer over the insulating layer to fill the contact hole; and
planarizing the second conductive layer to expose the capping layer.

15. The method according to claim 14, wherein the first conductive layer comprises a gate layer comprising an underlying gate dielectric layer, the spacer and the capping layer comprise a silicon nitride layer, the insulating layer comprises a boron phosphorus silicate glass (BPSG) layer, and the method further comprises forming a spacer insulating layer comprising an a undoped silicate glass (USG) layer covering the spacer and the capping layer.

16. The method according to claim 14, comprising selecting the amount of the fluorine (F)-containing species contained in the etchant so that the etchant has an etching ratio for each of the insulating layer, the spacer, and the capping layer relative to contaminants of 3 or less.

17. The method according to claim 14, comprising selecting the amount of the fluorine (F)-containing species contained in the etchant so that the etchant has an etching ratio for each of the insulating layer, the spacer, and the capping layer relative to contaminants of 1 or less.

18. The method according to claim 14, wherein:
the etchant has an etching ratio for each of the insulating layer, the spacer, and the capping layer relative to contaminants of not more than 3,
the alcohol comprises isopropyl alcohol (IPA),
the fluorine (F)-containing species comprises at least one of hydrofluoric acid (HF), fluoride ions (F⁻), and bifluoride ions (HF₂⁻), and
the etchant comprises not less than 80% by weight of the alcohol and less than 20% by weight of the fluorine (F)-containing species.

19. The method according to claim 14, wherein the alcohol comprises glycol,
the fluorine (F)-containing species comprises at least one of hydrofluoric acid (HF), fluoride ions (F⁻), and bifluoride ions (HF₂⁻), and
the etchant comprises not less than 80% by weight of the alcohol and less than 20% by weight of the fluorine (F)-containing species.

20. The method according to claim 14, wherein the etchant further comprises a surfactant as a dispersant for the fluorine (F)-containing species.

21. The method according to claim 14, wherein the etchant comprises less than 10% by weight water.

22. The method according to claim 14, wherein the step of cleaning the contact hole comprises using the etchant to remove etching residue and/or a native oxide present over the surface of the semiconductor substrate.
